(19) United States
(12) Patent Application Publication
(10) Pub. No.: US 2014/0057439 A1
(43) Pub. Date: Feb. 27, 2014

(54) Method of Forming Interlayer Dielectrics

(71) Applicants: JIANDONG ZHANG, Singapore (SG); Han Chuan Fang, Singapore (SG); jianjun Zhang, Singapore (SG); Xiaowei Shu, Singapore (SG); MIAO ZHANG, Singapore (SG)

(72) Inventors: JIANDONG ZHANG, Singapore (SG); Han Chuan Fang, Singapore (SG); jianjun Zhang, Singapore (SG); Xiaowei Shu, Singapore (SG); MIAO ZHANG, Singapore (SG)

(21) Appl. No.: 13/591,209

(22) Filed: Aug. 21, 2012

(51) Int. Cl. H01L 21/306

(52) U.S. Cl. 438/693; 257/E21.23

(57) ABSTRACT

A method of forming interlayer dielectric comprising the steps of forming a first undoped layer, forming in-situ and sequentially a doped layer and a second undoped layer on the first undoped layer, and planarizing the second undoped layer.

### BACKGROUND OF THE INVENTION

1. Field of the Invention

The present invention generally relates to a method of forming interlayer dielectrics. More particularly, the present invention relates to a method of forming interlayer dielectrics with stacked doped layers and undoped layers.

2. Description of the Prior Art

Interlayer dielectrics (ILD), more specifically, pre-metal dielectric (PMD), are the dielectric stacks between the polysilicon gate and the first-level metal layer. The film stack of ILDs should provide optimal planarization and cost-effectiveness at the designated technology node.

Over the years, ILDs have evolved from phosphor silicate glass (PSG) and/or borophosphosilicate glass (BPSG) for technologies of several microns, to TEOS CMP for 0.13 μm technologies and beyond. The phosphorus in the PSG layers can getter sodium ions and other device-degrading impurities as well as reduce the glass transition temperature of the as-deposited film in the following reflow process. The boron in the BPSG layers can further reduces the glass transition temperature without excessive phosphorus.

In actual process condition, the deposited interlayer dielectric structure would not have an even surface. The surface of the deposited interlayer dielectric structure would spread up-and-down with the topography of underlying device areas. Therefore, a chemical mechanical polishing (CMP) process is always necessary to planarize the interlayer dielectric structure in order to form the overlying multilevel metal layer. The present of CMP process in the process flow of interlayer dielectric structure may influence the overall throughput or the process cost.

Accordingly, it is necessary for the semiconductor industry to provide a novel and improved method for forming the interlayer dielectric structure with better throughput or the process cost.

### SUMMARY OF THE INVENTION

To improve the above-mentioned drawbacks in the method of prior art, a novel method of forming stacked interlayer dielectrics is provided in the present invention. The method of the present invention features the steps of in-situ and sequentially depositing the doped layer and the undoped layer in the same process tool to improve the overall throughput. Furthermore, the necessary planarization process for the interlayer dielectrics is performed after the deposition of all constituent layers, thus the underlying devices have less potential to be damaged.

The object of the present invention is to provide a method of forming interlayer dielectric comprising the steps of depositing a first undoped layer on a substrate, in-situ depositing a doped layer and a second undoped layer on first undoped layer, and planarizing the second undoped layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles.

In the drawings:

FIGS. 1-7 are cross-sectional views illustrating the process flow of forming an interlayer dielectric structure in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient details to enable those skilled in the art to practice the invention. Other embodiments may be utilized and structural, logical, and electrical changes may be made without departing from the scope of the present invention.

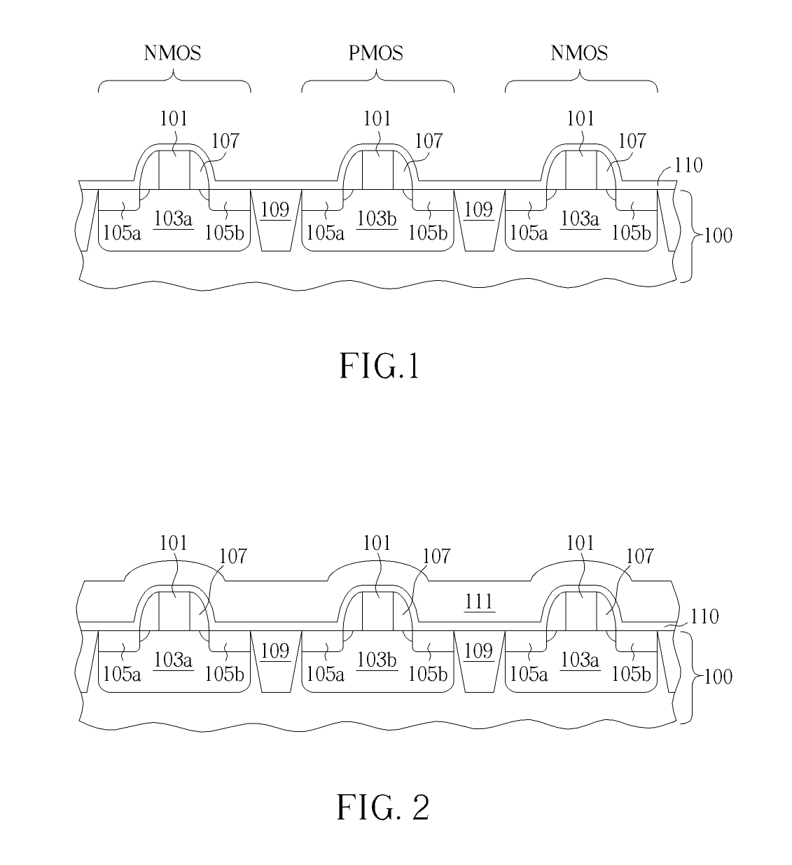

The embodiments will now be explained with reference to the accompanying drawings to provide a better understanding of the process of the present invention, wherein FIGS. 1-6 are cross-sectional views illustrating the process flow of forming a interlayer dielectric (ILD) structure in accordance with one embodiment of the present invention.

First, please refer to FIG. 1, a semiconductor substrate 100 is provided to serve as a base for forming semiconductor devices or layer structures thereon. In the present embodiment, the semiconductor substrate 100 comprises, but not limited to, a silicon substrate. In another embodiment, the substrate 100 may be, but not limited to, an epitaxial silicon substrate, a silicon germanium (SiGe) substrate, a silicon carbide (SiC) substrate, or a silicon-on-insulator (SOI) substrate, etc. The semiconductor substrate 100 has a device area for manufacturing various functional devices, components and/or layer structures, such as the CMOS structure composed of NMOS regions and PMOS regions, gate electrodes 101, P-wells 103a and N-wells 103b, source 105a and drain 105b, and spacers 107. A shallow trench isolation (STI) 109 is formed in the semiconductor substrate 100 to separate each NMOS and PMOS region. Moreover, a SiN layer 110 is deposited conformally on the surface of semiconductor substrate 100 to serve as a contact etch stop layer (CESL) in later contact forming process. The CMOS structure shown in FIG. 1 is an exemplary embodiment of present invention. In other embodiments, the device area of semiconductor substrate 100 may include other devices or components such as diodes, insulated gate bipolar transistor (IGBT), bipolar junction transistor (BJT), MOSFET, resistors, inductors, capacitors, various memory cells and/or metal lines.

In the present invention, the interlayer dielectric structure, especially in the pre-metal dielectrics, is a multilayer structure constituted of oxide-based organic dielectrics, such as BPSG (borophosphorosilicate glass), PSG (phosphosilicate glass), USG (undoped silicate glass) , with a dielectric constant of 3.9 or below, and preferably below 3.0. To protect the above-mentioned semiconductor devices from being degraded, usually, an undoped silicon film (ex. undoped silicate glass, USG) is deposited underneath the PSG layer of the interlayer dielectric structure. Furthermore, an additional overlying undoped silicate glass film is deposited on the PSG layer to serve as a cap layer. Therefore, the film stack of USG/PSG/USG layers is often used for the interlayer dielectrics in nowadays semiconductor technologies, especially for the pre-metal dielectric. Accordingly, the following preferred embodiment will take the stacked interlayer dielectric structure of USG/PSG/USG as an example to describe the process flow of the present invention. The use of USG/PSG/USG (or doped/undoped/ doped layer construction) stacked structured in interlayer dielectrics provides the advantage of gettering the device-degrading impurities from the device areas or active circuit regions of the wafer or substrate, thereby improving the yield of VLSI manufacturing.

Please refer now to FIG. 2, the process of forming the stacked interlayer dielectric starts after completing the manufacturing of semiconductor devices on/in the semiconductor substrate 100. The process flow starts with a step of depositing a first undoped layer 111 on the semiconductor substrate 100, more specifically, on the SiN layer 110. In the present invention, the first undoped layer 111 is formed conformally through a low temperature sub-atmosphere pressure chemical vapor deposition (LT-SACVD) for providing good gap filling capability on the uneven surfaces of the device area. Due to the conformal deposition, the surface of the first undoped layer 111 spreads up-and-down with the topography of the underlying semiconductor devices. In the present invention, the first undoped layer 111 maybe an undoped silicate glass (USG) layer with a thickness about 1000 Å.

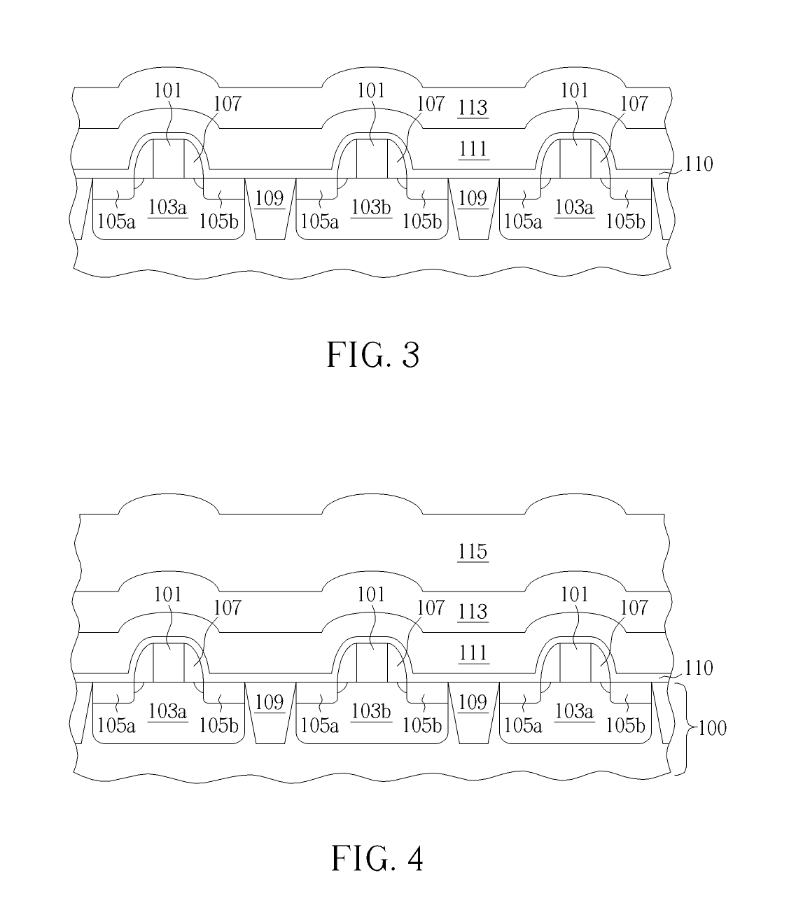

Then, please refer to FIG. 3, a doped layer 113 is deposited on the first undoped layer 111. The doped layer 113 may be formed conformally by plasma-enhanced tetraethoxysilane chemical vapor deposition (PE-TEOS CVD) as the surface of the doped layer 113 spreads up-and-down with the topography of underlying first undoped layer 111. The PE-TEOS CVD process may include several steps, such as PE-TEOS deposition, sputtering etchback, and PE-TEOS deposition. In the present invention, the doped layer 113 may be a phosphor silicate glass (PSG) layer or a borophosphosilicate glass (BPSG) layer with a thickness of about 2550 Å. In another embodiment, the doped layer 113 maybe formed by ozone tetraethoxysilane chemical vapor deposition (O₃-TEOS CVD) or high-density plasma chemical vapor deposition (HDPCVD).

After forming the doped layer 113, please refer to FIG. 4, a second undoped layer 115 (also referred to as a cap layer) is then deposited on the doped layer 113. The second undoped layer 115 may be formed conformally by plasma-enhanced tetraethoxysilane chemical vapor deposition (PE-TEOS CVD) as the surface of the second undoped layer 115 spreads up-and-down with the contour of underlying doped layer 113. The PE-TEOS CVD process may include several steps, such as PE-TEOS deposition, sputtering etchback, and PE-TEOS deposition. The second undoped layer 115 may be an undoped silicate glass (USG) layer with a thickness about 4700 Å. In other embodiment, the doped layer 113 may be formed by ozone tetraethoxysilane chemical vapor deposition (O₃-TEOS CVD) or high-density plasma chemical vapor deposition (HDPCVD).

Please note that one essential feature of present invention is that the second undoped layer 115 is in-situ and consecutively formed in the same process as the forming of doped layer 113. That is, for example, the doped layer 113 is first deposited on the first undoped layer 111 by a PE-TEOS CVD tool, the second undoped layer 115 is then deposited successively on the doped layer 113 by using the same PETEOS CVD tool without the sequence of loading the processed wafers or substrates out of the process chamber to another process tool. The forming of two different layers in-situ with one process tool may be achieved by introducing different process gases and applying different process parameters for corresponding layer structures. In the present invention, in-situ forming the doped layer 113 and the second undoped layer 115 in one process tool can allow the skip of unnecessary steps in conventional process flows, such as loading the process wafers or substrates in/out of the process tools and/or redundant precondition sequence, thereby improving the overall throughput and reducing the process cost by about 50%.

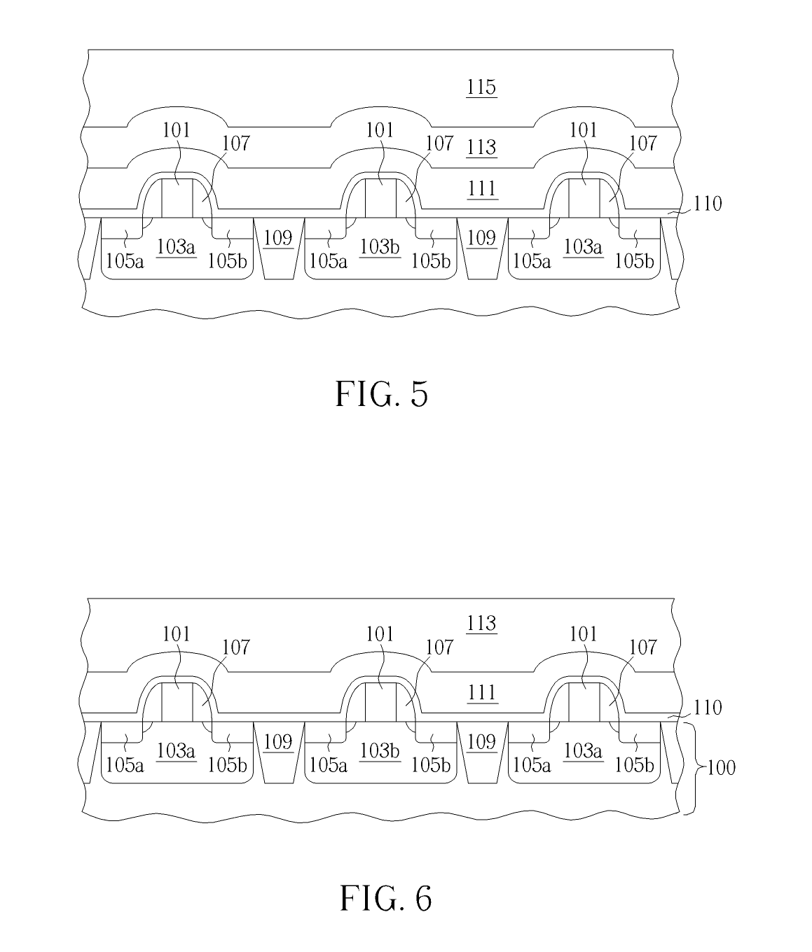

After forming the doped layer 113 and the second undoped layer 115, please refer to FIG. 5, the second undoped layer 115 is planarized by performing a chemical mechanical polishing (CMP) process. The thickness of the second undoped layer 115 is reduced in this process, for example, from 4700 Å to 4050 Å. Please note that the CMP process of the interlayer dielectric in the present invention is performed after the formation of the second undoped layer 115 (cap layer). The advantage of this approach of present invention is that, since the CMP process is performed after the formation of the thicker second undoped layer (about 4700 Å, much larger than the thickness of the doped layer 113, which is about 2550 Å), the CMP process may have less potential to damage the underlying semiconductor devices or components.

Alternatively, in another embodiment of present invention, please refer to FIG. 6, the CMP process of the interlayer dielectrics may be performed between the deposition of the doped layer 113 and the second undoped layer 115 rather than be performed after the deposition of the second undoped layer 115. That is, for example, the first undoped layer 113 and the doped layer 113 are first in-situ deposited by the same process tool, such as a LT-SACVD tool, and the CMP process is then performed to planarize the deposited doped layer 113. The second undoped layer 115 is finally deposited on the planarized doped layer 113. In this embodiment, preferably, the thickness of the deposited doped layer 113 should be increased, for example, about 5500 Å, much larger than the thickness of the doped layer 113 in first embodiment, which is about 2550 Å, in order to providing sufficient window for the following CMP process.

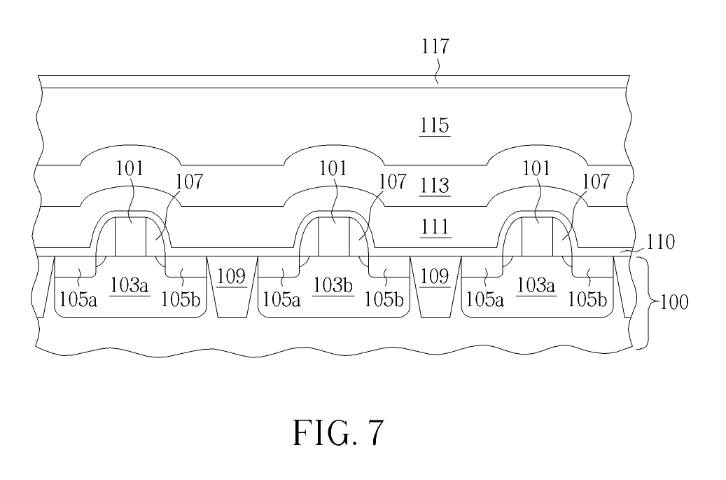

After forming the second undoped layer 115, finally, please refer to FIG. 7, a hard mask layer 117 is deposited on the planarized second undoped layer 115 for subsequent metal etching processes. The hard mask layer 117 may be a SION layer formed by a chemical vapor deposition process with a thickness of about 300 Å.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming an interlayer dielectric, comprising:
depositing a silicon nitride layer on a device area of a substrate;
depositing a first undoped layer on said silicon nitride layer;
depositing in-situ and sequentially a doped layer and a second undoped layer on said first undoped layer; and
performing a chemical mechanical polishing process to planarize said second undoped layer without exposing said doped layer, wherein said first undoped layer, said doped layer and said second undoped layer constitute said interlayer dielectric.

2. The method of forming an interlayer dielectric according to claim 1, wherein said first undoped layer is deposited by a sub-atmospheric pressure chemical vapor deposition (SACVD).

3. The method of forming an interlayer dielectric according to claim 1, wherein said first undoped layer is deposited by plasma-enhanced tetraethoxysilane chemical vapor deposition (PE-TEOS CVD), ozone tetraethoxysilane chemical vapor deposition (O₃-TEOS CVD), or high-density plasma chemical vapor deposition (HDPCVD).

4. The method of forming an interlayer dielectric according to claim 1, wherein said doped layer and said second undoped layer are deposited by plasma-enhanced tetraethoxysilane chemical vapor deposition (PE-TEOS CVD), ozone tetraethoxysilane chemical vapor deposition (O₃-TEOS CVD), or high-density plasma chemical vapor deposition (HDPCVD).

5. The method of forming an interlayer dielectric according to claim 1, further comprising depositing a hard mask layer on said second undoped layer.

6. The method of forming an interlayer dielectric according to claim 5, wherein said hard mask layer comprises a SION layer.

7. The method of forming an interlayer dielectric according to claim 1, wherein said first undoped layer comprises an undoped silicate glass (USG).

8. The method of forming an interlayer dielectric according to claim 1, wherein said doped layer comprises phosphor silicate glass (PSG) or borophosphosilicate glass (BPSG).

9. The method of forming an interlayer dielectric according to claim 1, wherein said second undoped layer comprises undoped silicate glass (USG).

10. The method of forming an interlayer dielectric according to claim 1, wherein said device area comprises transistors, diodes, MOSFET, resistors, inductors, capacitors, memory cells, or metal lines.
